(19) United States
(12) Patent Application Publication
(10) Pub. No.: US 2010/0021720 A1
(43) Pub. Date: Jan. 28, 2010

(54) Transparent coductive oxide and method of production thereof

(76) Inventors: Elena M. Shembel, Coral Springs, FL (US); Aleksandra Shimyryeva, Kiev (UA); Mykhailo Dusheyko, Kiev (UA); Tymofiy V. Pastushkin, Ft. Lauderdale, FL (US); Volodymyr Redko, Coral Springs, FL (US)

Correspondence Address: Enerize Corporation;Elena Shembel, 4956 Rothschild Dr, Coral Springs, FL, 33067-4134, US

(21) Appl. No.: 12/460,759

(22) Filed: Jul. 24, 2009

Related U.S. Application Data
(60) Provisional application No. 61/130,967, filed on Jul. 24, 2008.

(51) Int. Cl. B32B 5/16; B05D 3/06; C23C 14/34

(52) U.S. Cl. 428/323; 427/551; 204/192.14

(57) ABSTRACT

Novel effective method of vacuum evaporation and followed deposition of transparent conductive oxides on the polymer basis allows achieve the high technical and operational parameters of ITO film: transparency, conductivity, a high adhesion to a polymer substrate (especially in limiting the temperature of deposition no more than 60° C.), resistance to thermal shock, thermal cycles, humidity, etc. and providing relatively low cost without the use of precious metals. The transparent conductive oxides which are obtained according presented invention is generally characterized by nano structures with the size of nano crystals from 6 nm up to 25 nm. wherein a nano structure is distributed evenly across the surface. The value of transparency of the transparent conductive oxides ITO that were received according presented invention was 92% when the value of surface resistance was 12 ohms/□.

### CROSS-REFERENCE TO RELATED APPLICATIONS

None

### FEDERALLY SPONSORED RESEARCH

None

### SEQUENCE LISTING

None

### FIELD OF THE INVENTION

The present invention relates to the transparent conductive oxides (TCO) materials and more specifically to such materials on the flexible plastic substrates with properties that make it applicable as a thin film material in flat panel displays, as well as solar cells and PV modules, touch screens, architectural glass with solar control or low emissivity, antistatic glass, smart windows, electromagnetic shielding, and even DNA-selecting chips.

### BACKGROUND

Indium tin oxide (ITO, or tin-doped indium oxide) is a mixture of indium (III) oxide (In₂O₃) and tin (IV) oxide (SnO₂), typically 90% In₂O₃, 10% SnO₂ by weight. It is transparent and colorless in thin layers. In bulk form, it is yellowish to grey.

Indium tin oxide's main feature is its combination of electrical conductivity and optical transparency. However, a compromise has to be reached during film deposition, as high concentration of charge carriers will increase the material's conductivity, but decrease its transparency

Thin films of indium tin oxide are most commonly deposited on surfaces by electron beam evaporation, physical vapor deposition, or a range of sputter deposition technique.

The various type of the polymer film-substrate could be used, for examples, flexible poly(ethylene terephthalate) film (PET) or flexible polyethylene naphthalate film (PEN).

For various materials-substrate deposition of the transparent conductive oxide must be conducted under various temperatures. For examples PEN films are more stable under higher temperatures than are PET films. Therefore, deposition of the ITO on the PET film is a more complicated process because it is necessary to carry out the process of deposition at lower temperatures than in the case of the PEN films. When conduct process of TCO deposition it is a problem to provide a high level of the adhesion and transparency and low level of the resistance. Technologies and apparatus presented in current invention allow obtain the TCO film with low resistance and high transparency when conduct process of the deposition even under temperature less then 100C.

### BRIEF DESCRIPTION OF THE INVENTION

Novel effective process of vacuum evaporation and followed deposition of transparent conductive oxides on the polymer basis is presented here. This process provide the increasing transparency of the TCO and its adhesion to substrate, stability of the properties under mechanical and temperature stress. Meantime, process provide the low cost of fabrication and materials.

The transmission (transparency) and resistance are among the key requirements for TCO properties. It is a great problem to fabricate TCO that combines both high transmission and low resistance. In the method of production the TCO which is presented in the current invention it is possible to obtain TCO with a high transparency and a low resistant without additive of the side expensive materials like silver and other. The samples of TCO film based on indium tin oxides have a resistance less them 12 Ohm/square when transparency is near 90%.

Conditions of the TCO deposition and proportion of the TCO obtained are depended on the nature of the substrates. When compare deposition of TCO, for example ITO for polymer film PET And polymer film PEN the deposition of the ITO on the PET film is more complicated process compared with deposition of the ITO on the PEN film. The reason is that in the case of the PET film the process of deposition must be conducted at a lower temperature than in the case of the PEN film. Nonetheless, even with PET as flexible polymer substrate we achieved the high level of the ITO properties has been achieved due to special method of polymer film treatment before process of the deposition and due to the parameters of deposition.

Other important criterion of the TCO properties is the adhesion of the TCO to the substrate. This property is depended on the various factors, for example on the differences of the temperature coefficients of the linear expansion of the substrate and the TCO film. In the case not good adhesion between TCO and substrate the shear deformation occurs with the changes the temperature. This results in the emergence of micro-cracks in the film, which can be expanded to form the gross defects in the film.

The problems of the TCO properties and problem of the TCO cost were solved in the invention presented here due to use method developed.

### DESCRIPTION OF THE DRAWINGS

FIG. 1. Appearance vacuum chamber installer to obtain TCO films 101—cap, 102—vacuum gauge, 103—gas system lap, 104—system with the piezo ceramics for providing gas regulation.

FIG. 2. The vacuum unit which consists of a heater (201), the magnetron (202) and the carousel (204), on which six holders of the substrates are located (203).

FIG. 3 The system of heating and temperature stabilization. 301—contact less precision temperature controller, 302—thermocouple. 303—regulating resistance

FIG. 4 Magnetron sputtering system in this device is the round type magnetron with the diameter 125 mm. The target is a bath which is filled by alloy of initial material, for example alloy of the indium and tin (405) and is cooled with water (404); samarium-cobalt permanent magnets (401) are installed in a magnetron.

FIG. 5. The system for providing the gas consists from the device which directly provides the gas (502) and the control unit (501). A device to ensure a supply of gas (502) has piezo ceramics drive. Using pezostriktsionnoy ceramics for the regulation of the gap in the pipe is the basis of the principle of a device to ensure a supply of gas (502).

FIG. 6. Electric circuit for measuring the volt-ampere characteristics of samples ITO. 701—measuring the voltage. 702—measuring the current

FIG. 7. Volt-ampere characteristics of samples ITO under current of evaporation 500 MA, under different partial oxygen pressure in the mixture of the argon and oxygen: 801—0.09 Pa; 802—0.19 Pa; 803—0.23 Pa; 804—0.28 Pa; 805—0.37 Pa.

FIG. 8. Influence of the current running in magnetron on the ITO film conductivity

FIG. 9. Influence of the current, running in magnetron on the volt-ampere characteristics. is partial oxygen pressure in the mixture of the argon and oxygen is 0.23 Pa. 901—1000 mA; 902—750 mA; 903—500 mA.

FIG. 10. Dependences of resistance of ITO films on the temperature for different values of the partial pressure of oxygen: 1201—0.09 Pa; 1202—0.19 Pa; c, 1203—0.37 Pa; 1204—0.28 Pa.

FIG. 11. Dependences of resistance of ITO films on the temperature for different values of the current evaporation: 1301—1000 mA; 1302—750 mA; 1303—500 mA.

FIG. 12 AFM image of the surface film ITO, sample No. 20.

FIG. 13 AFM image of the surface film ITO, sample No 24

FIG. 14 AFM image of the surface film ITO, sample No 31

FIG. 15 a. AFM image of the surface film ITO, sample No 41

FIG. 15 b. AFM image of the surface film ITO, sample No 41

FIG. 16 AFM image of the surface film ITO, sample No 50

FIG. 17 Transparency of the ITO-PET sample No. 20

FIG. 18. Transparency of the PET polymer film.

FIG. 19 Transparency of the ITO without polymer substrate

FIG. 20 Transparency of the ITO-PET sample No. 50, prototype.

FIG. 21. Results of the test of the effect of the thermal cycle of ITO-PET sample obtained according presented invention.

FIG. 22 Dependence the transparency of the ITO from current of evaporation. pac [symbol] I [symbol] eH [symbol] for the wavelengths: 2201—650 nm; 2202—450 nm; 2203—350 nm

### DETAILED DESCRIPTION OF THE INVENTION

The method for producing condensed layers of the transparent conductive oxides from chemically active compounds is implemented as follows.

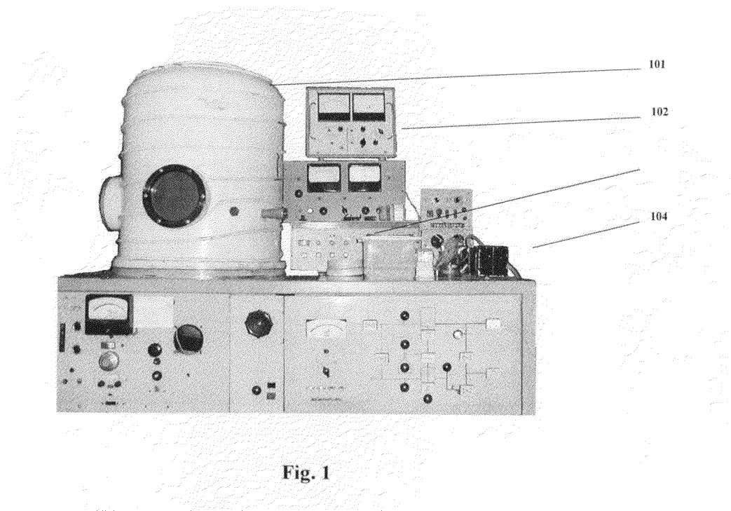

Processes of obtaining the layers of the transparent conductive oxide of ITO were conducted on a vacuum unit the appearance of which is shown in FIG. 1

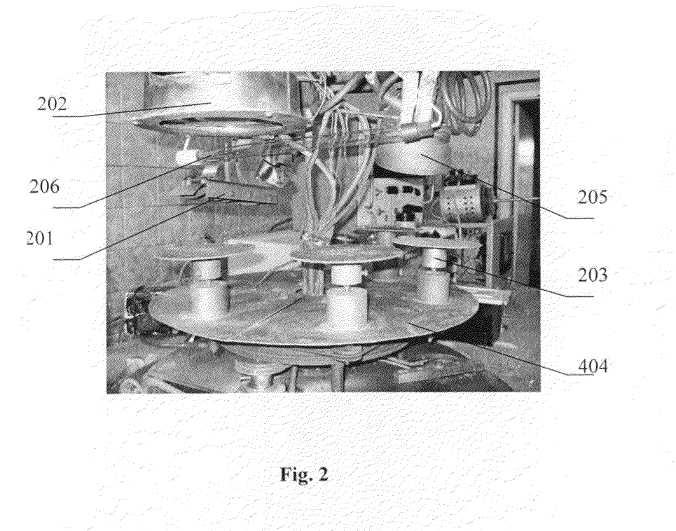

The vacuum unit (FIG. 2) consists of a heater (201), the magnetron (202) and the carousel (204), on which six holders of the substrates are located (203). The holders, together with the substrate alternately pass through the zone of heating and spraying. In doing so, at the same time they are rotated around its axis. This provides a high homogeneity of film thickness on the whole area of the substrate.

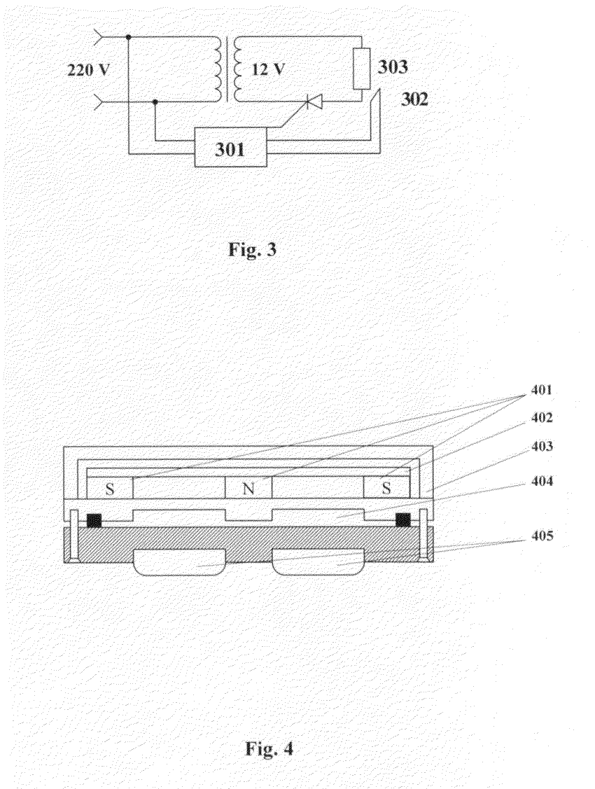

The heating of the substrates is provided by the systems for the heating and for stabilization the temperature of substrates. (FIG. 3)

Some of examples of the power of heating substrates could be on the region of ˜600 W, maximum temperature could be on the region—180° C., precision temperature—±2.5° C.

Magnetron sputtering system in this device is the round type magnetron with the diameter 125 mm (FIG. 4). The target is a bath which is filled by alloy of initial material, for example alloy of the indium and tin. (405) and is cooled with water (404). Samarium-cobalt permanent magnets (401) are installed in a magnetron.

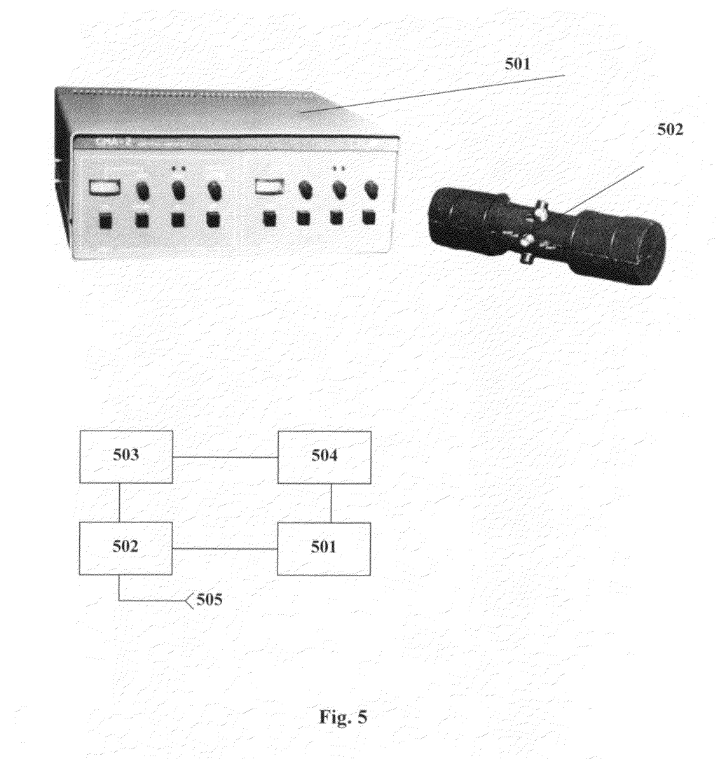

Limiting operating pressure in the chamber was 4·10-3 Pa. For the deposition the ITO films mixture of the argon and oxygen in the ratio (70:30)±15 was used. The working pressure of the mixture which is desired in the sputtering process was maintained through the system with two channels. (FIG. 5 a and 5 b). This system is designed for the goal to remote and to adjustable gases on two channels. This system is used in a variety of the processes: of electron-ion, ion-plasma and other facilities. In addition, during operation of the devices, with feedback, the system with a two channels allows to automatically maintain the pressure in the operating range of the working pressures

The system for providing the gas consists from the device which directly provide the gas (502) and the control unit (501). A device to ensure a supply of gas (502) has pezostriktsionny drive. Using pezostriktsionnoy ceramics for the regulation of the gap in the pipe is the basis of the principle of a device to ensure a supply of gas (502). As a result the number of gas which is fed into the system and for analysis is regulated.

Elongation piezo ceramics is directly proportional to voltage which is attached. Therefore the use of ceramics allows manage almost virtually without inertia the flow of gas and with a high accuracy remotely install the required pressure in the system. This can be done as a manual or automatic mode.

The control unit (501) provides remote system management (502) and provides the control of the system in automatic mode. The control unit (501) has a stabilized source of the voltage

The control unit provides an opportunity
smoothly regulate the output voltage within approximately form 40±10 V up to (1450±50) B;
monitor the availability of the output voltage by the integrated indicator;
switch from manual mode to automatic mode to regulation of the gas flow
change the phase and magnitude of reference voltage for proper operation in the automatic mode;
regulate the time constant amplifier in a wide operating range;
-disable (close) flow of the gas regardless of the mode of operation.

Device for supply the gas operates in the following mode. Working camera of the device is separated from the source of the gas by membrane. When the voltage is supplied on the plate of the piezo ceramics the mechanical pressure on the membrane decreases and the valve which closed the gas flow begins the opening the gas flow. By changing the value of the voltage which is supplied to the plate from the piezo ceramics it is possible greatly change the cross-section of holes for supply of gas. Consequently, the gas flow is also changing

The technological cycle of deposition of ITO films includes the following processes:

1. Installation of substrates on holders of the substrates.

2. Closing the cap of shell

3. Pumping the vacuum pressure, and in parallel provide the heating and the temperature stabilization of substrates

4. Activating the surface of the polymer substrate by an ion beam

5. Irradiating the surface of polymer substrates by ultraviolet light

6. Providing the working mixture of the gases argon and oxygen and the pressure which is required

7. Providing the power supply to the magnetron, set the regime of sputtering.

8. Sputtering the targets within a specified time.

9. During the deposition of transparent conductive oxides the ionic stimulation of the oxide synthesis process is conducted by treating of the growing oxide film surface by oxygen ions.

10. During the deposition of transparent conductive oxide layer along with ion stimulation of the oxide synthesis the surface of growing oxide film is irradiated by ultraviolet light.

11. During the deposition of transparent conductive oxides layers a pulsed feed of a gas mixture is applied

12. During the deposition substrate holders for the polymer substrate go alternately through heating and dispersion zones, concurrently turning around their axis, that leads to high uniformity of the film thickness along the whole substrate area.

13. Turning off power supply and magnetron systems overlap.

14. Turning off heating systems and temperature stabilization of substrates.

15. Supply the air or mixture of the gas inside of the chamber and opening the shell

The following technological parameters: the partial pressure of oxygen; the value of a current, running in magnetron; time of the deposition, and others affect the quality of TCO. Below are data on the range of operating parameters, which provide high-quality TCO films that are obtained according to the invention which is presented.
The partial oxygen pressure in the mixture of the argon and oxygen was in the operating range from 0.09 to 0.37 Pa;
The value of a current, running in magnetron was in the operating range from 500 mA up to 1000 MA;
Time of the deposition in the operating range from 5 to 15 min.
The energy of the ion beam for activated the surface of the polymer substrate before the deposition of transparent conductive oxide layer is activated by an ion beam with energy was from 0.7 keV up to 1.2 keV
A wave length of the ultraviolet light which could be used for additional irradiation of the surface of polymer substrate before the deposition of TCO layer was on operating range from 300 nm up to 400 nm.
A wave length of the ultraviolet light which could be used for irradiation of the surface of growing TCO film during deposition was on operating range from 300 nm up to 400 nm.
The pulse feed of a gas mixture which is consists of an exchange of the mixture of argon and oxygen to the argon was provided with the frequency in the operating range from 10 up to 100 Hz.

The properties of the transparent conductive oxide could be tested using the volt-ampere characteristics. During the experiments the measurement of the volt-ampere characteristics of transparent conductive oxides obtained at different modes were conducted:
Influence of the partial oxygen pressure in the mixture of the argon and oxygen during TCO deposition
Influence of the current, running in magnetron during TCO deposition

The electrical contact system for conducting experiments was formed using sputtering the titanium-nickel contacts through a mask with electron beam evaporation. The parameters for obtain the contact system were as following: accelerating voltage 12 kV, emission current was for titanium of 140 mA, and for nickel −200 mA; sputtering time for titanium was 2 min and for nickel was 10 min. Further, a mounting of the wires to the contact sites of the TCO film with the subsequent degreasing the surface of the films.

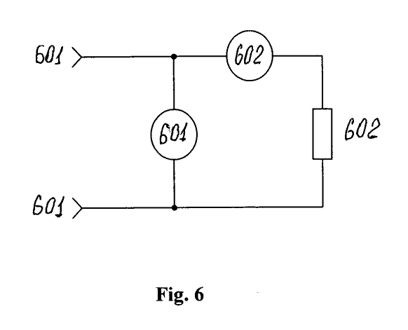

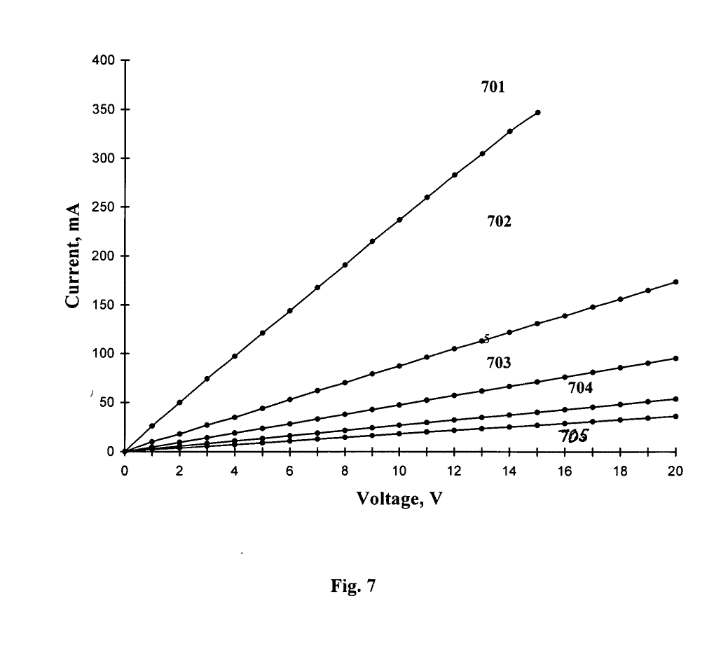

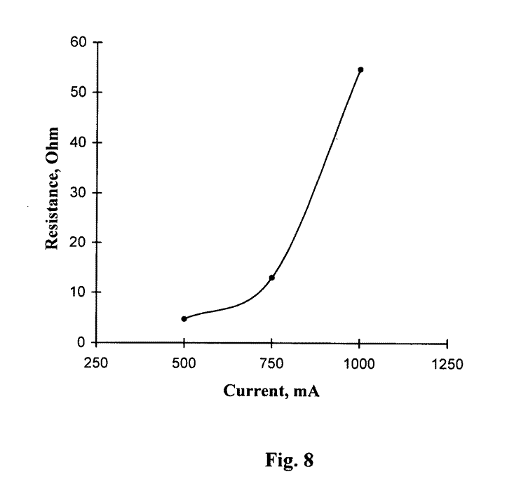

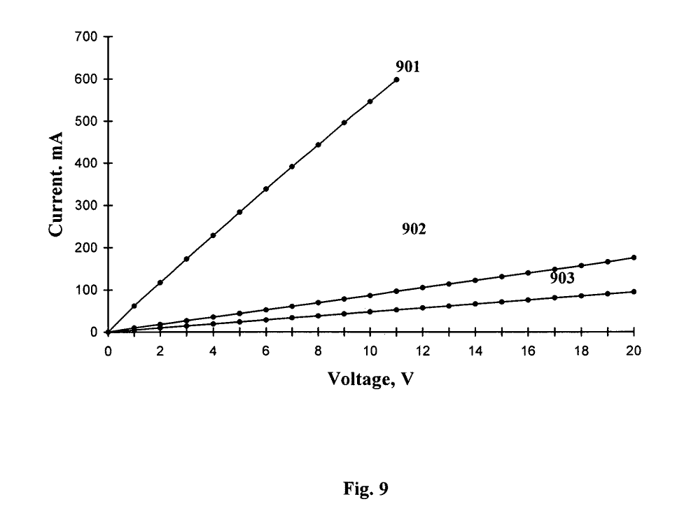

Electric circuit for the measuring the volt-ampere characteristics of samples ITO is shown in FIG. 6. For each measurement the value of current was fixed and then the measurement the value of voltage was conducted. The operating range of voltage was up to 20 V. The results of measurements are shown in FIG. 7 where influence of the partial oxygen pressure in the mixture of the argon and oxygen on the volt-ampere characteristics is presented, and on FIG. 9 where influence of the current, running in magnetron on the volt-ampere characteristics is presented. As shown for the ITO film the volt-ampere characteristics has a linear nature. On the FIG. 8 result of the influence of the current running in magnetron of the ITO film conductivity is presented.

Measurement of surface resistance was carried out also using additional two methods:
Four probes method.
Method using test-resistors, which are created by lithography.

An important characteristic of the properties of transparent conductive oxides is influence of the temperature on the conductivity. During the experiments the measurement of the influence of the temperature on the resistance of the TCO that were obtained at different modes were conducted. The modes were as following:
Various partial oxygen pressure in the mixture of the argon and oxygen during TCO deposition
Various the current, running in magnetron during TCO deposition.

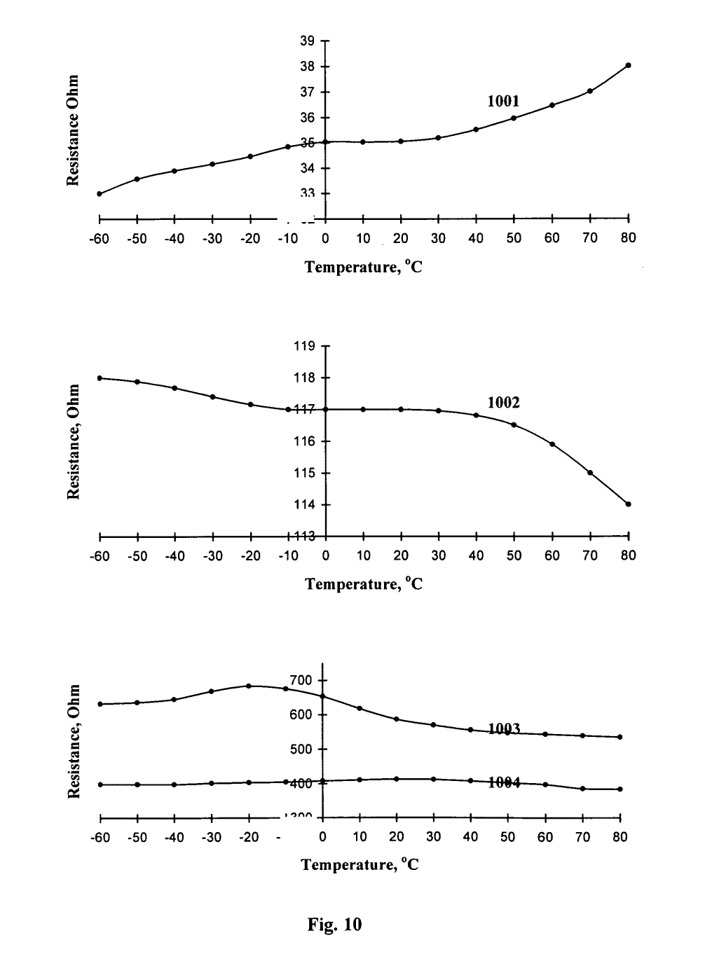

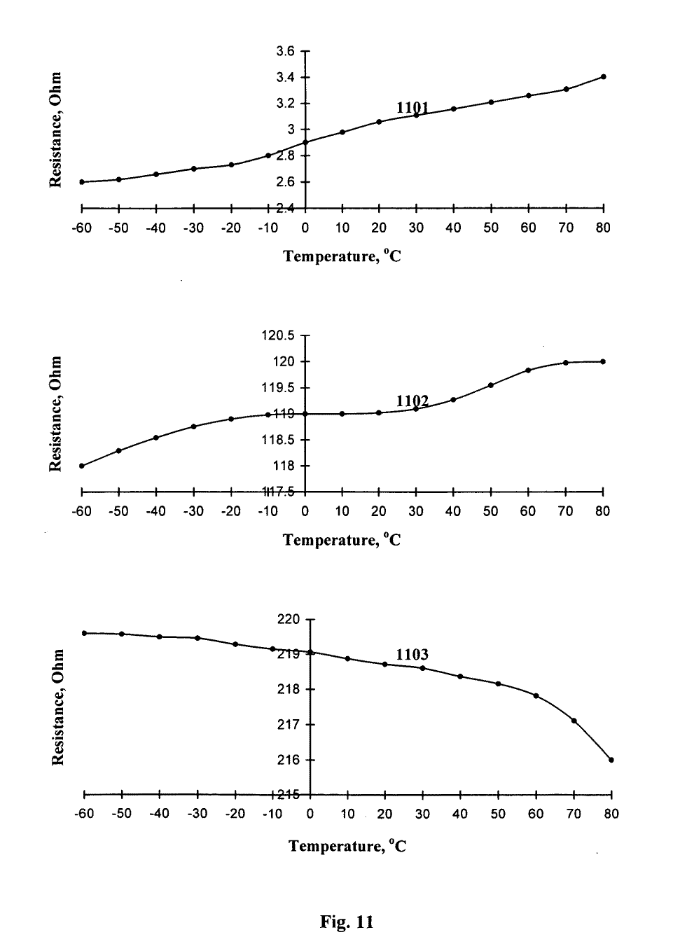

Resistance recorded at slow cooling and subsequent heating (−60° C.÷80° C.) with shutter speed at a fixed temperature (after every 10° C.) during 10 minutes to establish thermodynamic equilibrium. Results of the test are presented on the FIGS. 10 and 11.

As was noted above the volt-ampere characteristics of the samples transparent conductive oxide-ITO films that were obtained with method presented in the current invention are subject to a linear law. With the increasing the partial oxygen pressure in the mixture of the argon and oxygen during TCO deposition the resistance of the ITO film increased (film conductivity decreases).

With the increasing the partial oxygen pressure in the mixture of the argon and oxygen during TCO (ITO) deposition (P=0.19÷0.28 Pa) a long stable areas, where virtually resistance is constant are observed. Further growth of the partial pressure of oxygen (P=0, 37 Pa) leads to the formation of a film with semiconductor properties, as manifested in the temperature dependence of resistance. At the same time, there are areas with a negative temperature coefficient (10⁻³). In this case, the conduction mechanism is due to the increasing concentration of charge carriers and due to decreasing of mobility due to scattering by phonon vibrations. In the area of negative temperatures have increased resistance to a change in mobility, but in the positive temperature dual mechanism: an increase of concentration of charge carriers due to thermo generation and reduced mobility due to phonon scattering.

With the increasing the current, running in magnetron during TCO deposition the resistance of the ITO decreased (conductivity increased). Moreover, inside the operating range of the current which is running in magnetron during TCO deposition from 500 up to 750 mA of conductivity change is slow, and if the value of current is more than 750 mA is observed a sharp change in the conductivity. These changes relate to changes in film structure and content of oxygen. Increasing oxygen content leads to a transition from the metal nature conductivity of the ITO film to the semiconductor nature of the conductivity. This is clearly seen in the study according to the resistance of films on the temperature.

Under the current which is running in magnetron during TCO deposition equal to 1000 mA and a low value of the partial oxygen pressure in the mixture of the argon and oxygen during TCO (ITO) deposition, the ITO films have a low resistance. With the rise in temperature the resistance increases. This is typical for materials with metallic character of conductivity. The main mechanism of the temperature dependence is due to a change in mobility due to phonon scattering. At the same time, in spite of the metallic nature of conductivity in contrast to metals, the value is ˜2·10-3 l/grad. That is significantly lower compared with the known metals (aluminum, cobalt, nickel, copper and platinum).

The surface resistance of ITO films is in the range of 10-30 ohm/□, which is of interest to manufacturers of solar panels. Such high level of conductivity transparent conductive oxide which is accompanied with a high level of the transparency of this oxides were achieved due to special combination of process parameters such as velocity dispersion, the composition of the gas mixture, the composition of the target, the distance between the target and substrate, substrate temperature, spraying time and other parameters mentioned aboveσ

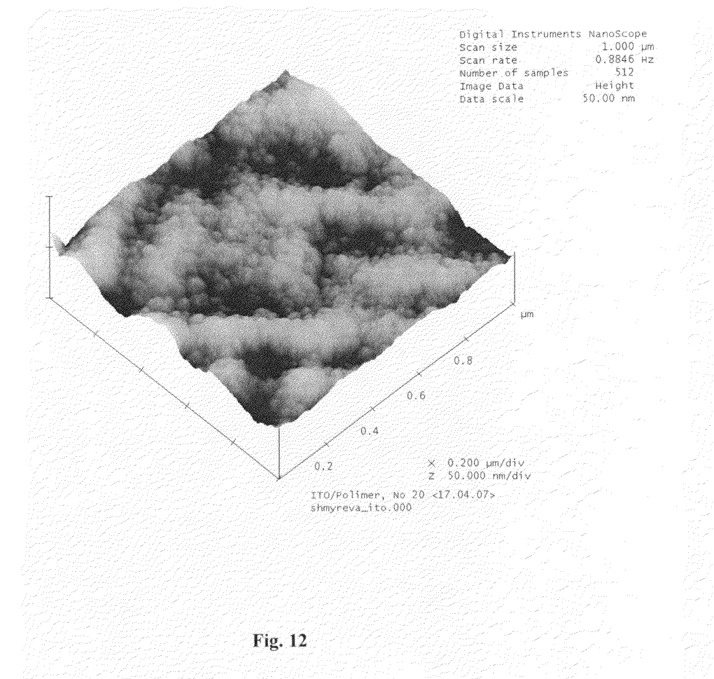

Electrical and optical properties of transparent conductive oxide film are determined by their structural properties. Structural properties of samples of the thin film transparent conductive oxides on the flexible substrate polymer film-poly (ethylene terephthalate) film (PET) are studied using atomic force microscopy (AFM) (Nano Scope 111a Quadrexed Dimension 3000) and presented at the FIGS. 12, 13, 14,15a, 15b and 16.

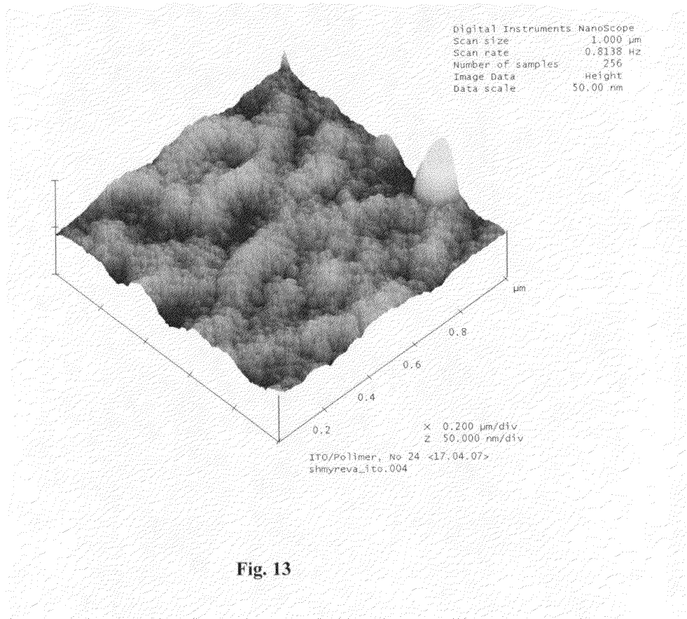

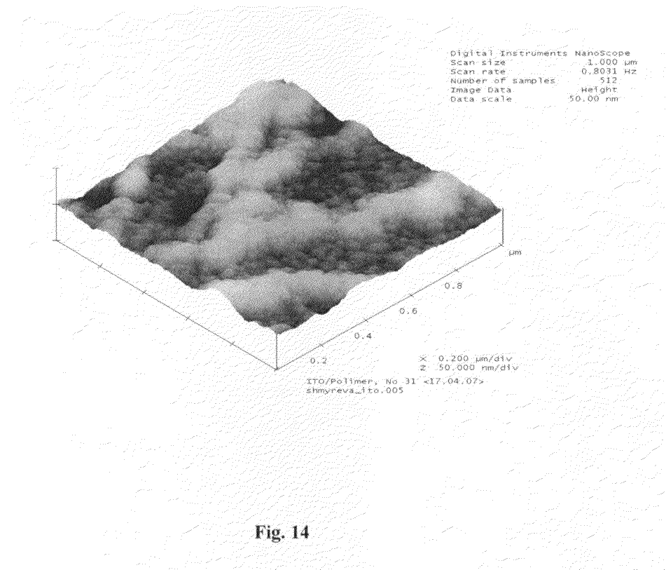

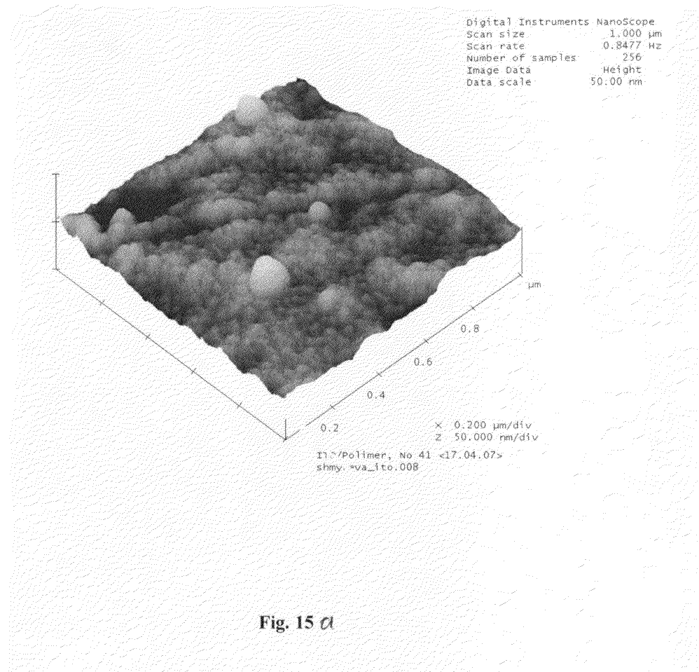

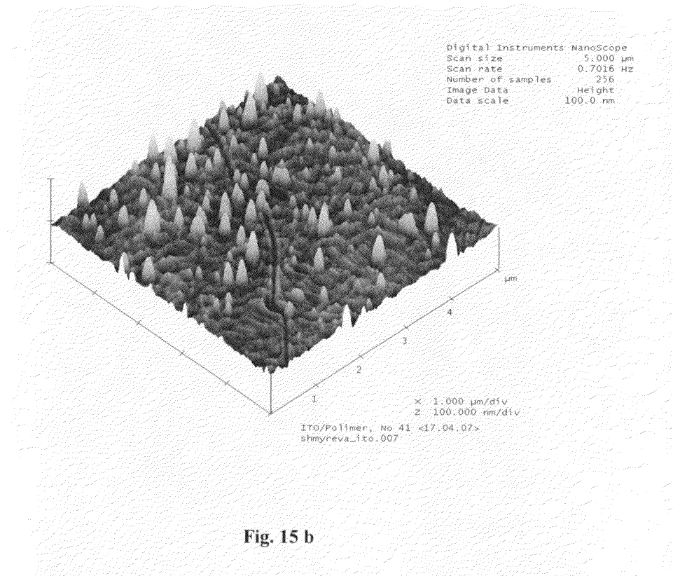

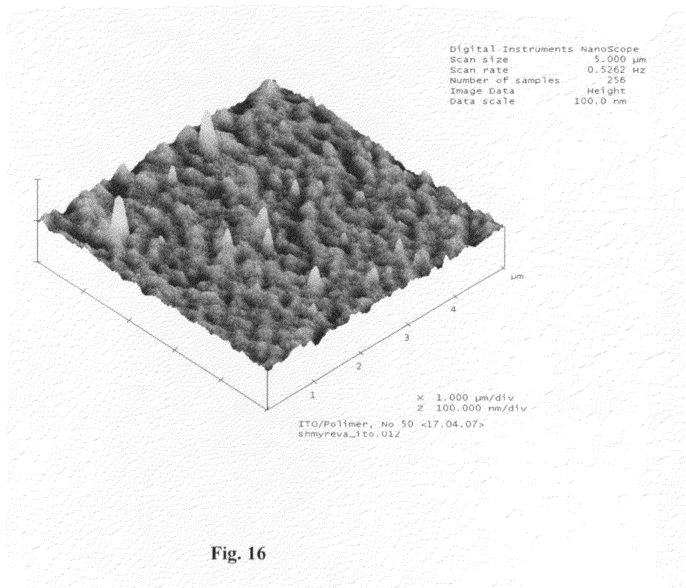

On the AFM imagery the orientation direction of growth the film at an angle of 350 is clearly showed. This is due to that before the deposition of transparent conductive oxide layer on a polymer substrate, the surface of the polymer substrate is activated by an ion beam with energy between 0.7 keV and 1.2 keV and angle of incidence between 15°-60°. For the samples 20 (FIG. 12), 24 (FIG. 13) and 31 (FIG. 14) the angle of incidence was 30°.

The surface of the polymer film in the case of the sample No 41 was no activated by an ion beam before the deposition of transparent conductive oxide layer on a polymer substrate with the angle of incidence. In the image of the AFM of the transparent conductive oxide sample No. 41 no orientation direction

For films of ITO, obtained according to the presented invention, are nano structured with the size of nano crystals in the region of 6-25 nm. The film of the ITO sample No. 20 is the uniform structure across the surface and has a minimum size of the nano crystals.

Sample the ITO film number 50, which is available for sale and can be regarded as a prototype, has no a regular-oriented structure. At the same time, the high optical and electrophysical properties of the sample No. 50 are close to the properties of the sample number 20, which is obtained in accordance with the invention. A study of the film sample No. 50 showed the presence in it of silver and gold. Due to the presence of these additives surface resistance of the specimen No. 50 is at the level of 10 ohms/□ and the transparency is 80%.

The method of obtaining films of transparent conductive oxide according presented invention allow obtain film with low resistance and high level of transparency without using high cost alloying additives.

Transmittance (spectral characteristics) was determined by Spectrophotometer CF-46 over an operating wavelength range of 200 nm to 950 nm.

The integrated tests included:
Determining the effect of thermal cycles from the temperature of minus 40° C. to a temperature of plus 75° C. The duration of the cycles was four hours. Monitoring of resistance was conducted after every three cycles.
Tests to determine effects of high temperature (75° C.).
Test to determine effects of low temperature (minus 45° C.)
Test to determine the effects of relative humidity (90%).

Evaluation of the stability of the properties of the optically transparent electrodes is confirmed by the ratio of the resistance after and before the test treatment.

These spectral characteristics confirm that films of the transparent conductive oxides that are obtained according presented invention with substrate flexible poly(ethylene terephthalate) film (PET) have resistance 10 ohm/□ and optical transparency in the visible range (450-750 nm) at the level of 0.7-0.85. At the same time for the sample No. 50 which is from market and could be the prototype to this invention the level of the optical transparency in the visible range (450-750 nm) consist 0.6-0.8. The transparent conductive oxides according that obtained according invention which is presented have a high level transparency in yellow and red area of the spectrum. At the same time for the samples No. 50 have seen a dramatic decrease in the transparency of the yellow-red area, which is undesirable for use in solar cells.

Method presented in current invention allows manage the transparency of the film of the transparent conductive oxide at different wavelengths. In the field of ultraviolet radiation at a wavelength λ=350 nm the transparency decreases when the current of the evaporation increases. Transparency is depended on the partial pressure of oxygen in the mixture argon and oxygen during the process of TCO obtaining. Maximum of the transparency is obtained when the pressure during deposition is 0.28 Pa. This pattern is related to changes in the nanostructure TCO film and in the refractive index.

In the blue-blue field of λ=450 nm dependence of the transparency of TCO film on the partial pressure of oxygen in the mixture argon and oxygen during the process of TCO obtaining has a minimum at a pressure of 0.19÷0.23 Pa and a maximum when the current of evaporation is 700÷800 mA. At a wavelength λ=650 nm (red light) the transparency practically does not depend on the mode of evaporation-deposition of the transparent conductive oxide because the special method treatment of surface of substrate before the film deposition and treatment the surface of TCO film during deposition is used. Such behavior of the characteristics is associated with the difference of the refractive index for different wavelengths of light and conditions of the light distribution inside the transparent conductive oxide.

In Table 1 the properties of the transparent conductive oxide (indium tin oxide-ITO on the flexible poly(ethylene terephthalate film (PET) that were obtained under different conditions are presented.

TABLE 1
Properties of the transparent conductive oxide (indium tin oxide-ITO on the flexible
poly(ethylene terephthalate film (PET) that were obtained under different conditions

| | | | | | | Ion bean | Irradiation |
|---|---|---|---|---|---|---|---|
| | | | | | | activated surface | by |
| | | Resistance | Trsaparency y, % | Transparency, % | Transparency, % | before process,. | ultraviolet |
| No Sample | Substrate | OM/□ + 58 | at λ = 450 nm | at λ = 550 HM | at λ = 700 HM | Time, min. | light. |
| 20 | 005., | 12 | 0.74 | 0.81 | 0.8 | 1.0 | + |
| | PET | | | | | | |
| 39 | 005., | 10 | 0.7 | 0.78 | 0.82 | 1.5 | − |
| | PET | | | | | | |
| 40 | 005., | 10 | 0.7 | 0.78 | 0.82 | 1.5 | − |
| | PET | | | | | | |
| 50 prototype | 005. | 10 | 0.7 | 0.77 | 0.7 | — | − |
| | PET- | | | | | | |
| 21 | 005. | 13.2 | 0.7 | 0.75 | 0.82 | 1.5 | + |
| | [symbol] | | | | | | |
| | p, PET | | | | | | |
| 34 | 005. [symbol] | 14.9 | 0.66 | 0.72 | 0.79 | 1.0 | − |
| | [symbol] , | | | | | | |
| | PET | | | | | | |
| 22 | 005. | 17.5 | 0.6 | 0.72 | 0.8 | 1.0 | − |
| | [symbol] , | | | | | | |
| | p, PET | | | | | | |
| 35 | 005. [symbol] | 16.75 | 0.7 | 0.8 | 0.8 | 1.2 | + |
| | [symbol] , | | | | | | |
| | PET | | | | | | |
| 36 | 007. [symbol] | 16.5 | 0.7 | 0.8 | 0.8 | 1.2 | + |
| | [symbol] , | | | | | | |
| | PET | | | | | | |
| 25 | 005. | 22 | 0.8 | 0.75 | 0.82 | 1.5 | + |
| | [symbol] | | | | | | |
| | p, PET | | | | | | |
| 27 | 005. | 22 | 0.72 | 0.82 | 0.82 | 1.7 | − |
| | [symbol] | | | | | | |
| | p, PET | | | | | | |
| 42 | 001. | 20 | | | | | |
| | [symbol] | | | | | | |
| | p, PET | | | | | | |
| 31 | 005. | 26.2 | 0.7 | 0.82 | 0.85 | 1.7 | − |
| | [symbol] | | | | | | |
| | p, PET | | | | | | |
| 33 | 005. | 30 | 0.68 | 0.8 | 0.9 | 2.0 | − |
| | [symbol] | | | | | | |
| | p, PET | | | | | | |

The transparent conductive oxide-ITO-PET that were obtained according invention presented here are generally characterized by nano structures with the size of nano crystals approximately 6-25 nm. Sample No. 20 has a nano structure that is distributed evenly across the surface, with minimum sized nano crystals.

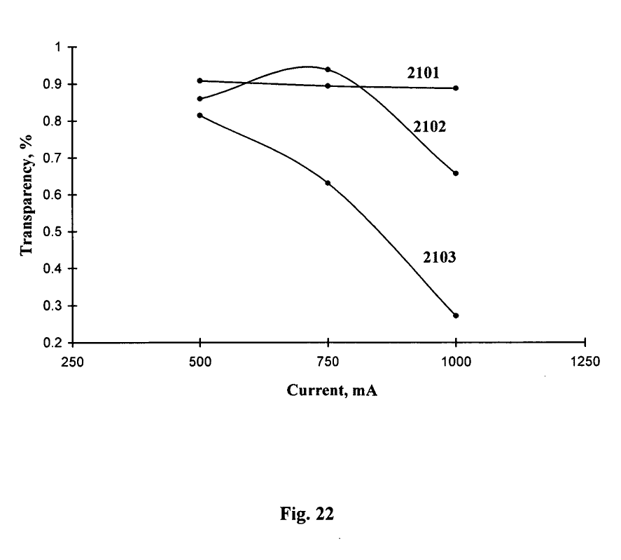

FIG. 22 presents the results of study of the effect of oxygen pressure on the transparency of ITO films for the three selected wavelengths, which demonstrate controllability of the technological process for forming a film with a given opacity in a given spectral range.

### EXAMPLES

The present invention is further illustrated by the following examples, which without limiting the scope of the present invention, describe various ways to make and use the present invention

### Example 1

Transparency was determined over the wavelength range from 200 nm to 950 nm Equipment: Spectrophotometer CF-46.

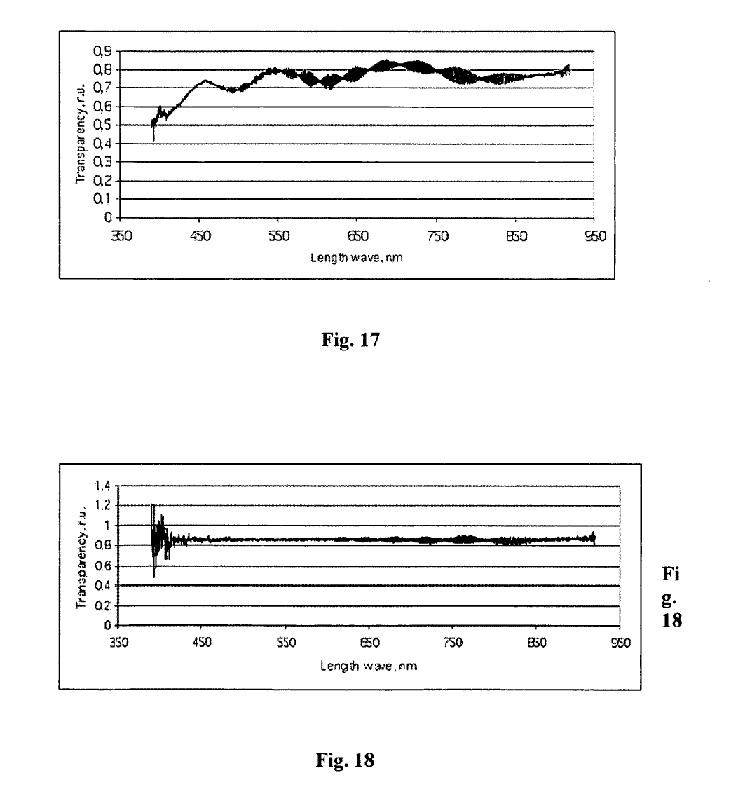

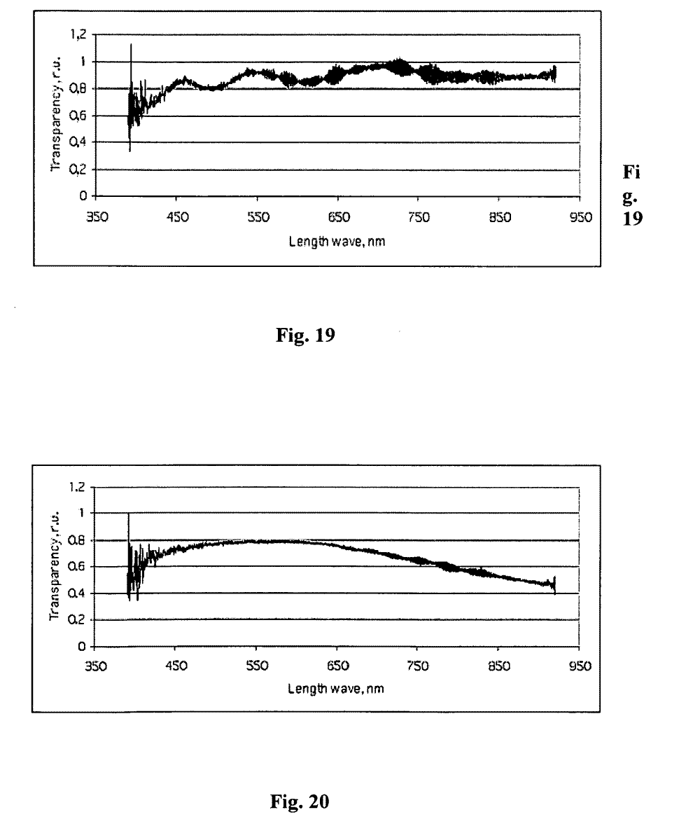

The following transparency-generated results are shown below:
1. Transparency of the sample ITO-PET No. 20 obtained according presented invention (FIG. 17)
2. Transparency of PET polymer film (FIG. 18)
3. Transparency of the sample ITO No. 20 without polymer substrate obtained according presented invention. (FIG. 19)
4. Transparency of the sample ITO-PET No. 50, prototype, with additional components that included in ITO. (FIG. 20)

The comparison of the transmittances for the Enerize Corporation ITO-PET sample No. 20 and ITO-PET sample No. 50 from DuPont shows that although the two samples have essentially equal resistances the Enerize Corporation sample has higher transparency. Over the visible spectrum range (450-750 nm), sample 20 has an optical transmission at 0.7 to 0.85 while the Dupond sample No. 50 has the optical transmission of 0.6 to 0.8.

For the prototype (sample No. 50) there is a sharp decrease in transparency in the yellow-red spectral region, which is not desirable for use in solar cells.

Sample 20 has a high level of the transparency at 550 nm, which is in accordance with the stated requirements of G24i.

The different level of the transparency in the different spectrum ranges is associated with differences in the index of refraction for different wavelengths and the conditions of the light distribution in the ITO film.

Method developed according presented invention for deposition transparent conductive oxides allows changes in the nano structure of the ITO due the change the parameters of the process of deposition. As a result, the light distribution in the ITO film is changed, which, in turn alters the transparency of the film in the different wavelength regions of the spectrum. Based on this technology, it is possible to improve the transparency of the films in the yellow and red area visible spectrum range and in the shorter wavelength ranges of the visible spectrum.

The ITO-PET film sample No. 50 is not aimed structured but the electro-optical properties are similar to the samples No. 20. The evaluation of sample No. 50 showed that the ITO includes silver and gold, which allows achievement of a surface resistance of 10 Ohms/square while maintaining a high level of transparency (see below).

The ITO-PET film which was obtained according presented invention does not include silver and gold and have low resistance and high level of transparency because the special parameters of evaporation-deposition.

### Example 2

One of the main criteria for assessing the quality of adhesion of the ITO film to the polymer substrate is the test of the effect of the high temperature and the thermal cycling. Due to differences of temperature coefficients of linear expansion of the substrate and the ITO film shear deformation occurs with changes the temperature. This results in the emergence of micro-cracks in the film, which can expand to form gross defects in the film. This process leads to an increase in ITO film resistance.

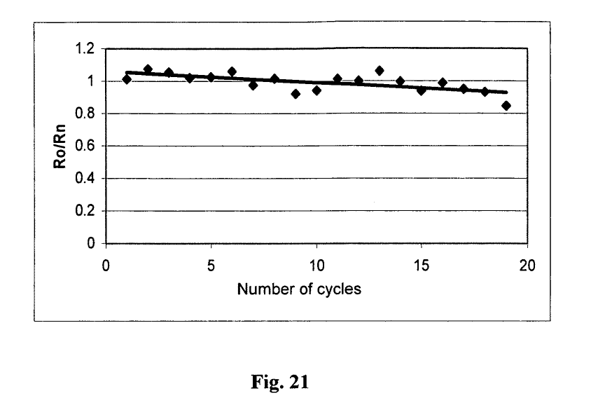

The correlation between the mechanical tests at multiple twisting (flexing) and temperature cycling tests was confirmed. Results of the test of the effect of the thermal cycle of ITO-PET sample are shown in the FIG. 21.

Results of the test confirm the high level of the stability of the ITO-PET electrode that was deposited using technology according presented invention. The change of the resistance during thermal cycling did not exceed 5-7%.

### CLOSURE

While various embodiments of the present invention have been shown and described, it will be apparent to those skilled in the art that many changes and modifications may be made without departing from the invention in its broader aspects. The appended claims are therefore intended to cover all such changes and modifications as fall within the true spirit and scope of the invention.

We claim:

1. A vacuum deposition method for production of transparent conductive oxide layers based on metal oxide compositions wherein before the deposition of transparent conductive oxide layer on a polymer substrate, the surface of the polymer substrate is activated by an ion beam with energy between 0.7 keV and 1.2 keV and angle of incidence between 15°-60°, and wherein during the deposition of transparent conductive oxide layer the ionic stimulation of the oxide synthesis process is conducted by treating of the growing oxide film surface by oxygen ions.

2. The method of claim 1 wherein before the deposition of the transparent conductive oxide layer the surface of polymer substrates is additionally irradiated by ultraviolet light.

3. The method of claim 2 wherein the ultraviolet light has a wave-length in the operating range from 300 nm up to 400 nm

4. The method of claim 1 wherein during the deposition of transparent conductive oxide layer along with ion stimulation of the oxide synthesis the surface of growing oxide film is irradiated by ultraviolet light

5. The method of claim 4 wherein the ultraviolet have a wavelength in the operating range from 300 up to 400 nm.

6. The method of claim 1 wherein the ion stimulation of the transparent conductive oxide during synthesis is conducted by a flow of oxygen ions falling to the surface of the growing film with an incidence angle of between 15° . . . 60° and a process of the ionization of oxygen occurs by means of an ion-plasma gun.

7. The method of claim 1 wherein process is spent into the medium of the argon-oxygen mixture

8. The method of claim 7 wherein ratio between the argon and oxygen on mixture is (70:30)±15.

9. The method of claim 1 wherein during the deposition of transparent conductive oxides layers a pulsed feed of a gas mixture is applied.

10. The method of claim 9 wherein the pulse feed of a gas mixture consists of an exchange of the mixture argon and oxygen to the argon with the frequency 10-100 Hz.

10. The method of claim 1 wherein magnetron spattering is used for vacuum deposition.

11. The method of claim 1 wherein the metal oxide compositions include mixtures of indium and tin oxides; oxide of zinc; oxides of indium or other metal oxides.

12. The method of claim 11 wherein the metal oxide compositions are alloyed by aluminum, gallium, silver, gold or other or mixture of these metals.

13. The method as in claim 1 wherein substrate holders for the polymer substrate go alternately through heating and dispersion zones, concurrently turning around their axis that leads to high uniformity of the film thickness along the whole substrate area.

14. The method of claim 1 wherein the activation/preliminary purification of the surface of polymer substrate by ionic ablation which is carried out using and ion-plasma gun located at the angle from the substrate where the polymer carrier is located.

15. The method of production as in claim 1 wherein the value of the dispersion current is in the operating range from 500 mA up to 1000 mA.

12. A method of production as in claim 7 wherein the partial oxygen pressure in the mixture is between 0.09÷0.37 Pa;

13. A transparent conductive oxide which is characterized by nano structures with the size of nano crystals from 6 nm up to 25 nm. wherein a nano structure is distributed evenly across the surface.

14. A transparent conductive oxide as in claim 13, wherein the value of transparency of the transparent conductive oxides ITO is 92% when the value of surface resistance is 12 ohms/□.

14. A transparent conductive oxide as in claim 13, wherein the flexible substrate is polymer film for examples, flexible poly(ethylene terephthalate) film (PET) or flexible polyethylene naphthalate film (PEN).
